(19) United States
(12) Patent Application Publication
(10) Pub. No.: US 2021/0313764 A1
(43) Pub. Date: Oct. 7, 2021

(54) Emitter array with uniform brightness

(71) Applicant: Apple Inc., Cupertino, CA (US)

(72) Inventors: Yazan Z. Alnahhas, Mountain View, CA (US); Oyvind Svensen, San Jose, CA (US); Weiping Li, Fremont, CA (US); Yuval Tsur, Tel Aviv (IL)

(21) Appl. No.: 17/221,856

(22) Filed: Apr. 5, 2021

Related U.S. Application Data
(60) Provisional application No. 63/005,327, filed on Apr. 5, 2020.

(51) Int. Cl. H01S 5/042; H01S 5/42; H01S 5/183

(52) U.S. Cl. CPC H01S 5/04254; H01S 5/423; H01S 5/04256; H01S 5/18344; H01S 5/18311

(57) ABSTRACT

An optoelectronic device includes a semiconductor substrate and an array of emitters disposed on the substrate, including at least first emitters disposed in a central zone of the array and second emitters disposed in at least one peripheral zone of the array, surrounding the central zone. The array includes at least one cathode and at least one anode disposed on opposing sides of the emitters. The first emitters have a first resistance between the at least one cathode and the at least one anode, and the second emitters have a second resistance, greater than the first resistance, between the at least one cathode and the at least one anode. A drive circuit is coupled to apply a selected voltage between the at least one cathode and the at least one anode so as to cause the emitters to emit optical radiation.

### CROSS-REFERENCE TO RELATED APPLICATION

This application claims the benefit of U.S. Provisional Patent Application 63/005,327, filed Apr. 5, 2020, which is incorporated herein by reference.

### FIELD OF THE INVENTION

The present invention relates generally to integrated optoelectronic devices, and particularly to emitter arrays.

### BACKGROUND

Effective heat dissipation is one of the major challenges in design of high-power optoelectronic emitters, such as vertical-cavity surface-emitting lasers (VCSELs). Such devices generate large amounts of heat in the emitter active regions, resulting in high emitter junction temperatures, which tend to reduce VCSEL efficiency and lead to a reduced optical power output at a given drive current. Increased temperatures also shift the emission wavelength, degrade the quality of the laser modes, and reduce operating lifetime and reliability. In VCSEL array devices, inefficient heat dissipation causes temperature non-uniformity among emitters, leading to variations in emitter optical power and wavelength across the array.

### SUMMARY

Embodiments of the present invention that are described herein provide improved emitters arrays and methods for their fabrication and use.

There is therefore provided, in accordance with an embodiment of the invention, an optoelectronic device, including a semiconductor substrate and an array of emitters disposed on the substrate, including at least first emitters disposed in a central zone of the array and second emitters disposed in at least one peripheral zone of the array, surrounding the central zone. The array includes at least one cathode and at least one anode disposed on opposing sides of the emitters. The first emitters have a first resistance between the at least one cathode and the at least one anode, and the second emitters have a second resistance, greater than the first resistance, between the at least one cathode and the at least one anode. A drive circuit is coupled to apply a selected voltage between the at least one cathode and the at least one anode so as to cause the emitters to emit optical radiation.

In some embodiments, the emitters include vertical-cavity surface-emitting lasers (VCSELs). In one embodiment, the VCSELs include respective oxide apertures, which have respective first diameters in the first emitters and respective second diameters, greater than the first diameters, in the second emitters, thereby causing the second resistance to be greater than the first resistance.

Additionally or alternatively, the VCSELs include respective mesas, and the at least one anode includes a plurality of anodes disposed respectively over the mesas of the VCSELs, including first anodes disposed over the mesas of the first emitters and having a first contact area between the first anodes and the mesas, and second anodes disposed over the mesas of the second emitters and having a second contact area, which is smaller than the first contact area, between the second anodes and the mesas, thereby causing the second resistance to be greater than the first resistance. In one embodiment, the first anodes have a first width, and the second anodes have a second width, which is less than the first width. Additionally or alternatively, the anodes are annular, such that each anode has a central opening over an active area of a respective VCSEL, and the central opening of the first anodes has a first diameter, while the central opening of the second anodes has a second diameter, which is greater than the first diameter.

In some embodiments, the at least one peripheral zone includes a first peripheral zone surrounding the central zone and a second peripheral zone surrounding the first peripheral zone, wherein the second emitters in the second peripheral zone have a third resistance, which is greater than the second resistance.

Additionally or alternatively, the optical radiation emitted by the array of emitters defines a pattern having a given angular width, and the device includes a diffractive optical element (DOE), which is configured to split the emitted optical radiation into multiple diffused replicas of the pattern, while deflecting the replicas at different, respective angles so as to cover an angular range greater than the angular width of the pattern. In a disclosed embodiment, the apparatus includes a projection lens, which is configured to defocus the pattern that is projected onto the DOE.

There is also provided, in accordance with an embodiment of the invention, a method for illumination, which includes forming an array of emitters on a semiconductor substrate, including at least first emitters disposed in a central zone of the array and second emitters disposed in at least one peripheral zone of the array, surrounding the central zone. The array includes at least one cathode and at least one anode disposed on opposing sides of the emitters. The first emitters have a first resistance between the at least one cathode and the at least one anode, and the second emitters have a second resistance, greater than the first resistance, between the at least one cathode and the at least one anode. A selected voltage is applied between the at least one cathode and the at least one anode so as to cause the emitters to emit optical radiation.

There is additionally provided, in accordance with an embodiment of the invention, a method for illuminating a field of view, which includes specifying a baseline exposure level in terms of a baseline intensity that is to be directed toward the field of view over a nominal temporal duration. An array of emitters is driven to illuminate the field of view with a power selected such that an average intensity of illumination of the field of view by the array is less than the baseline intensity, and an actual temporal duration of the exposure is extended relative to the nominal temporal duration so as to provide a total exposure level of the field of view that is equal to the baseline exposure level.

In one embodiment, driving the array includes reducing an output power level of the emitters. Additionally or alternatively, driving the array includes operating the emitters intermittently for short periods, which are interleaved with intervals in which the array is not driven to emit radiation.

The present invention will be more fully understood from the following detailed description of the embodiments thereof, taken together with the drawings in which:

### BRIEF DESCRIPTION OF THE DRAWINGS

FIG. 1 is a schematic side view of a flood illumination projector, in accordance with an embodiment of the invention;

FIG. 2 is a schematic frontal view of an emitter array device, in accordance with an embodiment of the invention;

FIG. 3 is a schematic sectional view of a single VCSEL in the array of FIG. 2, in accordance with an embodiment of the invention; and

FIG. 4 is a plot that schematically illustrates a method for illuminating a field of view, in accordance with an alternative embodiment of the invention.

### DETAILED DESCRIPTION OF EMBODIMENTS

Arrays of emitters, such as an integrated array of VCSELs, are subject to thermal crosstalk, i.e., a part of the heat generated in each emitter dissipates to its neighbors. Consequently, the emitters in the central zone of the array will absorb more heat and operate at a higher temperature than the emitters in peripheral zones, surrounding the central zone. Therefore, the emission efficiency of the emitters in the central zone (i.e., the optical power output relative to the electrical power input) will be lower than that in the peripheral zones. Consequently, when the entire array is driven with the same driving voltage, the emission from the central zone will be weaker than from the peripheral zones. These problems of uneven heat dissipation and emission nonuniformity become more severe as the array size becomes smaller and optical output power demands increase.

Embodiments of the present invention that are described herein provide methods and device designs that are directed toward reducing the temperature gradients over such arrays, and thus achieving more uniform emission. In some of these embodiments, an array of emitters, formed on a semiconductor substrate, includes a central group of emitters in the central zone of the array, and one or more peripheral groups of emitters in corresponding peripheral zones of the array, surrounding the central zone. The array comprises at least one cathode and at least one anode disposed on opposing sides of the emitters. The emitters in the central group are designed physically to have a lower resistance between the anode and cathode than the emitters in the peripheral group or groups.

As a result of this variation in resistance, when a drive circuit applies a selected voltage between the cathode and the anode, a relatively higher current will flow through each of the emitters in the central zone than through the emitters in the peripheral zone or zones. The difference in current, and thus the difference in the input power applied to the emitters in the central zone relative to those in the peripheral zones, is chosen so as to compensate for the reduction in efficiency in the central zone due to the temperature gradient. By judicious design, the optical output power of the emitters across the entire array can be made roughly uniform, notwithstanding the temperature gradient.

In alternative embodiments, the temperature gradients are reduced by control of the driving voltage. For example, a lower voltage may be applied to the entire array for a longer period in order to achieve a given total exposure power; or the voltage may be applied during a sequence of short emission intervals, with the voltage turned off between the intervals to allow for the temperature gradient to even out. As another alternative, the central group of emitters may be driven at a higher voltage than the peripheral group or groups, via different, respective electrodes, in order to compensate for the temperature gradient.

In the embodiments that are described below, the emitters are assumed to by VCSELs. Alternatively, the principles of the present invention may be applied, mutatis mutandis, to other emitters of optical radiation. (The term “optical radiation” is used in the context of the present description and in the claims to refer to electromagnetic radiation in any of the visible, infrared, and ultraviolet ranges.) All such alternative embodiments are considered to be within the scope of the present invention.

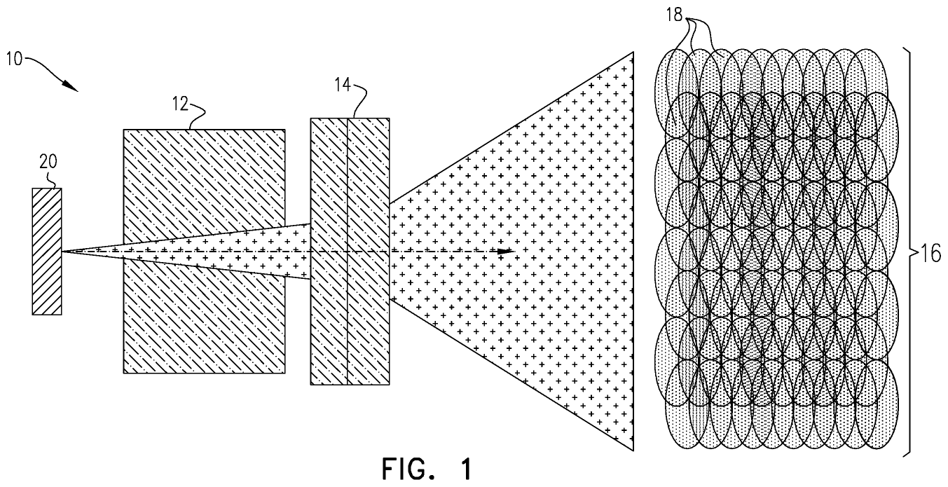

FIG. 1 is a schematic side view of a flood illumination projector 10, in accordance with an embodiment of the invention. This projector is shown and described here as a non-limiting example of the application of a laser emitter array device 20, such as a VCSEL array, in which uniformity of optical power output is important. Optics 12 form the beams emitted by the array into a pattern having a given angular width. The optics may be designed so that the pattern is intentionally defocused and thus diffused. A diffractive optical element (DOE) 14 splits the optical radiation into multiple defocused replicas 18 of the pattern, while deflecting the replicas at different, respective angles so as to cover an angular range 16 greater than the angular width of the pattern.

A frontal view of the projected radiation is shown at the right side of the figure. If the output of device 20 is nonuniform, for example with higher optical intensity around the edges of the array than in the central zone due to variations in operating temperature, a pattern of stripes will appear in the projected radiation. This pattern will be even more marked if DOE 14 generates tiled replicas of the array output pattern, rather than overlapping replicas 18 as in FIG. 1. This pattern of stripes is reduced or eliminated entirely in the present embodiment by applying greater electrical driving power to the VCSELs in the central zone of the array, relative to those in the peripheral zones.

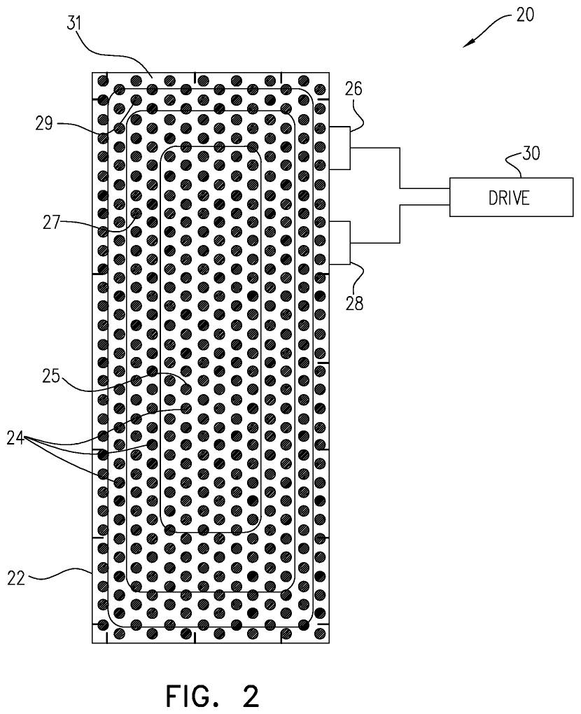

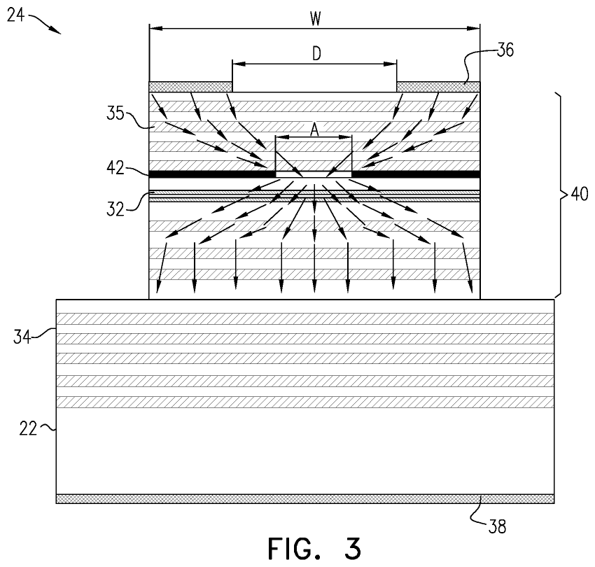

Reference is now made to FIGS. 2 and 3, which schematically illustrate features of emitter array device 20 in which this sort of graduated driving power scheme is applied, in accordance with an embodiment of the invention. FIG. 2 is a schematic frontal view of device 20, while FIG. 3 is a schematic sectional view of a single VCSEL 24 in the array.

Device 20 comprises a semiconductor substrate 22, such as a silicon or III-V semiconductor chip. The array of VCSELs 24 is formed on the substrate by a process of epitaxial deposition and photolithography. The steps of this process are known in the art, except that emitters 24 are made to have different values of electrical resistance depending on their location in the array, for example using one or more of the techniques illustrated in FIG. 3 and described below.

A drive circuit 30 applies a selected voltage between an anode terminal 26 and a cathode terminal 28 of device 20, which causes the emitters to emit optical radiation. Cathode terminal 28 is connected to a common cathode 38 on substrate 22, while anode terminal 26 is connected to individual anodes 36 of VCSELs 24 via conductors (not shown) on the substrate. Alternatively, device 20 may contain larger or smaller numbers of anodes and/or cathodes, connected respectively to one or more anode and cathode terminals on substrate 22. In the present embodiment, it is assumed, for reasons of economy and compactness of fabrication, that the same voltage is applied across all of VCSELs 24 in the array via terminals 26 and 28; alternatively, in other embodiments (not shown in the figures), different voltages may be applied to different VCSELs or groups of VCSELs.

As shown in FIG. 2, VCSELs 24 are divided among several zones: a central zone 25, which is surrounded by an inner peripheral zone 27, which itself is surrounded by an intermediate peripheral zone 29, surrounded in turn by an outer peripheral zone 31. Alternatively, device 20 may comprise a smaller or larger number of different peripheral zones, and possible only a single peripheral zone surrounding the central zone. In operation of device 20, VCSELs 24 in the central zone are expected to reach the highest operating temperature, with the temperature dropping gradually through the peripheral zones to the outer peripheral zone, in which the operating temperature will be lowest. Consequently, as explained above, VCSELs 24 in the outer peripheral zone will operate at the highest efficiency, with efficiency dropping gradually through the other peripheral zones to the central zone.

To counteract these temperature effects, VCSELs 24 in central zone 25 have a lower resistance between cathode 38 and anode 36 than the VCSELs in peripheral zones 27, 29, 31. Therefore, for any given driving voltage, the VCSELs in the central zone will draw a higher current, and thus a higher electrical power, than the VCSELs in the peripheral zones. By the same token, VCSELs 24 in inner peripheral zone 27 may have a lower resistance than those in intermediate peripheral zone 29, which in turn have a lower resistance than those in outer peripheral zone 31. The resistances are chosen so that the product of the electrical power consumed by the temperature-dependent efficiency of the VCSELs remains roughly uniform across the array.

FIG. 3 illustrates a number of ways in which this differential resistance can be implemented. These implementations can be used individually or in any suitable combination in order to achieve the desired resistance gradient. Alternatively, other techniques for controlling resistance differentially among the emitters in an array may be used, as will be apparent to those skilled in the art after reading the present description.

VCSEL 24 comprises one or more quantum well (QW) emission layers 32, which are sandwiched between a lower distributed Bragg reflector (DBR) 34 and an upper DBR 35. DBRs 34 and 35 are formed by depositing successive layers of high- and low-refractive-index materials on substrate 22, as is known in the art. The upper layers of each VCSEL 24 are etched in a photolithographic process to define a narrower mesa 40, of width W, which contains upper DBR 35, emission layers 32, and possibly a part of lower DBR 34, as shown in FIG. 3. An oxide layer 42 within mesa 40 is etched laterally inward to leave a narrow central aperture of diameter A. Both the current flowing between anode 36 and cathode 38 (illustrated by arrows in the figure) and the optical radiation output by emission layers 32 are confined to pass through this aperture.

In one embodiment, the resistance between anode 36 and cathode 38 is controlled by varying the sizes of the oxide apertures (i.e., varying diameter A) in oxide layer 42. VCSELs 24 in the central zone of the array have a larger oxide aperture, with an aperture diameter greater than those in the peripheral zones. As the aperture size decreases, the current path narrows, resulting in an increase of resistance in the VCSELs in the peripheral zones relative to those in the central zone. In practice, the smaller aperture size can be achieved by designing the photolithographic mask that is used in etching mesas 40 so that the VCSELs in the peripheral zones have gradually narrower mesas than those in the central zone. Consequently, following the lateral etching step, which is performed uniformly over the entire array, the apertures remaining in oxide layer 42 in the peripheral VCSELs will be smaller than those in the central VCSELs.

Additionally or alternatively, the contact areas of anodes 36 with mesas 40 of the respective VCSELs 24 can be made smaller in the peripheral zones than in the central zone of device 20. The smaller contact area results in greater resistance of the peripheral VCSELs relative to the central VCSELs. The contact area can be controlled by appropriate design of the mask that is used in photolithographic etching of anodes 36. As anodes 36 typically have an annular shape, with a central opening through which the laser radiation exits VCSEL 24, two dimensions of the anodes can be varied for this purpose, as illustrated in FIG. 3:
1) The width W of anodes 36 on VCSELs 24 in the central zone may be greater than that of the anodes in the peripheral zones.
2) The diameter D of the central opening of anodes 36 on VCSELs in the peripheral zones may be greater than that of the anodes in the central zone.
   Either or both of these dimensions of anodes 36 can be varied in order to achieve the desired variation in resistance over the zones of the array. Controlling resistance by varying the contact areas of anodes 36 is advantageous, relative to changing the oxide aperture size, in that it has little or no effect on the optical beam width and divergence of the VCSELs.

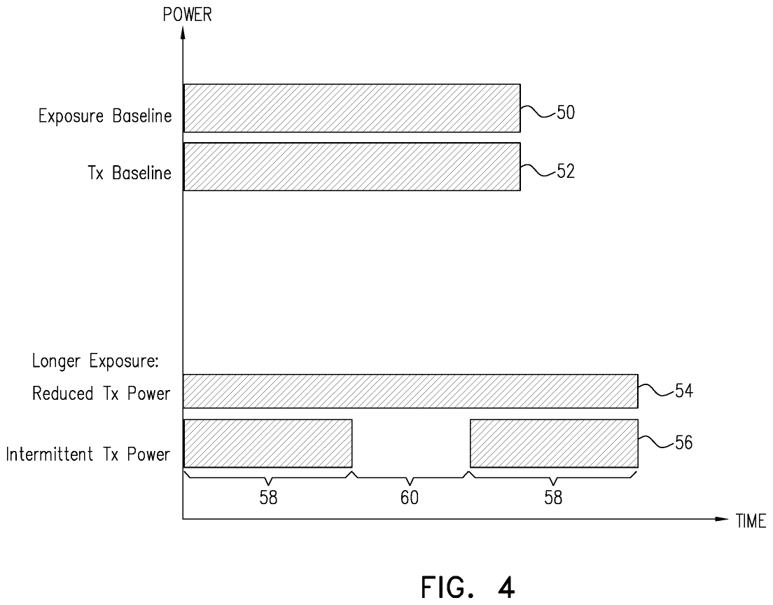

FIG. 4 is a plot that schematically illustrates a method for illuminating a field of view, in accordance with an alternative embodiment of the invention. This method may be applied using device 20, in conjunction with the design features described above. Alternatively, the method of FIG. 4 may be applied using emitter arrays of other types, in which the resistance of the emitters is approximately uniform over the entire array.

The present method uses an array of emitters with a specified exposure level, as illustrated by an exposure baseline plot 50 in FIG. 4. The height of this plot represents the baseline illumination intensity (i.e., power per unit area), while the width represents the nominal temporal duration of the exposure. The total, integrated exposure level is the product of the intensity by the duration, represented by the area of exposure baseline plot 50. In the absence of undesirable thermal effects, the exposure would be achieved by operating the array of emitters at a certain output power level for the specified duration, as illustrated by a Tx baseline 52 in FIG. 4.

In the present embodiment, however, the temperature gradient over the array during emission is reduced by driving the array of emitters with a power selected so that the average intensity of illumination is reduced while extending the exposure duration. To maintain the desired total, integrated exposure level, the output power level of the emitters can be reduced, while the exposure time is increased, as illustrated by a plot 54 labeled “Reduced Tx Power.” Alternatively or additionally, the emitters may be operated intermittently for short periods 58, interleaved with intervals 60 in which the array is not driven to emit radiation and is thus able to spread its heat more uniformly, as illustrated by a plot 56 labeled “Intermittent Tx Power.”

The choice of exposure may be a fixed design choice in certain instances, whereas in other cases the exposure choice may be dynamically changed depending on device operation. In one embodiment, a system in which an emitter array device of this sort is installed may be configured to assess a risk of overheating, and may shorten or extend the exposure based on this risk. For example, the system may be configured to measure one or more temperature signals (which may be indicative of ambient temperatures and/or system temperatures), and these temperatures may be used to determine the length of exposure. At colder ambient temperatures (where the risk of overheating is lower), a shorter exposure may be used, whereas at warmer ambient temperatures (where the risk of overheating is higher), the exposure may be lengthened. Additionally or alternatively, the frequency of operation of the array or other nearby components that may generate heat may also be considered in determining the exposure length.

It will be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. An optoelectronic device, comprising:
a semiconductor substrate;
an array of emitters disposed on the substrate, including at least first emitters disposed in a central zone of the array and second emitters disposed in at least one peripheral zone of the array, surrounding the central zone, the array comprising at least one cathode and at least one anode disposed on opposing sides of the emitters, the first emitters having a first resistance between the at least one cathode and the at least one anode, and the second emitters having a second resistance, greater than the first resistance, between the at least one cathode and the at least one anode; and
a drive circuit, coupled to apply a selected voltage between the at least one cathode and the at least one anode so as to cause the emitters to emit optical radiation.

2. The device according to claim 1, wherein the emitters comprise vertical-cavity surface-emitting lasers (VCSELs).

3. The device according to claim 2, wherein the VCSELs comprise respective oxide apertures, which have respective first diameters in the first emitters and respective second diameters, greater than the first diameters, in the second emitters, thereby causing the second resistance to be greater than the first resistance.

4. The device according to claim 2, wherein the VCSELs comprise respective mesas, and wherein the at least one anode comprises a plurality of anodes disposed respectively over the mesas of the VCSELs, including first anodes disposed over the mesas of the first emitters and having a first contact area between the first anodes and the mesas, and second anodes disposed over the mesas of the second emitters and having a second contact area, which is smaller than the first contact area, between the second anodes and the mesas, thereby causing the second resistance to be greater than the first resistance.

5. The device according to claim 4, wherein the first anodes have a first width, and the second anodes have a second width, which is less than the first width.

6. The device according to claim 4, wherein the anodes are annular, such that each anode has a central opening over an active area of a respective VCSEL, and wherein the central opening of the first anodes has a first diameter, while the central opening of the second anodes has a second diameter, which is greater than the first diameter.

7. The device according to claim 1, wherein the at least one peripheral zone comprises a first peripheral zone surrounding the central zone and a second peripheral zone surrounding the first peripheral zone, wherein the second emitters in the second peripheral zone have a third resistance, which is greater than the second resistance.

8. The device according to claim 1, wherein the optical radiation emitted by the array of emitters defines a pattern having a given angular width, and wherein the device comprises a diffractive optical element (DOE), which is configured to split the emitted optical radiation into multiple diffused replicas of the pattern, while deflecting the replicas at different, respective angles so as to cover an angular range greater than the angular width of the pattern.

9. The device according to claim 8, and comprising a projection lens, which is configured to defocus the pattern that is projected onto the DOE.

10. A method for illumination, comprising:
forming an array of emitters on a semiconductor substrate, including at least first emitters disposed in a central zone of the array and second emitters disposed in at least one peripheral zone of the array, surrounding the central zone, the array comprising at least one cathode and at least one anode disposed on opposing sides of the emitters, such that the first emitters have a first resistance between the at least one cathode and the at least one anode, and the second emitters have a second resistance, greater than the first resistance, between the at least one cathode and the at least one anode; and
applying a selected voltage between the at least one cathode and the at least one anode so as to cause the emitters to emit optical radiation.

11. The method according to claim 10, wherein the emitters comprise vertical-cavity surface-emitting lasers (VCSELs).

12. The method according to claim 11, wherein forming the array comprises forming respective oxide apertures in the VCSELs such that the oxide apertures have respective first diameters in the first emitters and respective second diameters, greater than the first diameters, in the second emitters, thereby causing the second resistance to be greater than the first resistance.

13. The method according to claim 11, wherein forming the array comprises etching respective mesas of the VCSELs, wherein the at least one anode comprises a plurality of anodes disposed respectively over the mesas of the VCSELs, such that first anodes disposed over the mesas of the first emitters have a first contact area between the first anodes and the mesas, and second anodes disposed over the mesas of the second emitters have a second contact area, which is smaller than the first contact area, between the second anodes and the mesas, thereby causing the second resistance to be greater than the first resistance.

14. The method according to claim 13, wherein the first anodes have a first width, and the second anodes have a second width, which is less than the first width.

15. The method according to claim 13, wherein the anodes are annular, such that each anode has a central opening over an active area of a respective VCSEL, and wherein the central opening of the first anodes has a first diameter, while the central opening of the second anodes has a second diameter, which is greater than the first diameter.

16. The method according to claim 10, wherein the at least one peripheral zone comprises a first peripheral zone surrounding the central zone and a second peripheral zone surrounding the first peripheral zone, wherein the second emitters in the second peripheral zone have a third resistance, which is greater than the second resistance.

17. The method according to claim 10, wherein the optical radiation emitted by the array of emitters defines a pattern having a given angular width, and wherein the method comprises applying a diffractive optical element (DOE) to split the emitted optical radiation into multiple diffused replicas of the pattern, while deflecting the replicas at different, respective angles so as to cover an angular range greater than the angular width of the pattern.

18. A method for illuminating a field of view, comprising:
specifying a baseline exposure level in terms of a baseline intensity that is to be directed toward the field of view over a nominal temporal duration; and
driving an array of emitters to illuminate the field of view with a power selected such that an average intensity of illumination of the field of view by the array is less than the baseline intensity, and an actual temporal duration of the exposure is extended relative to the nominal temporal duration so as to provide a total exposure level of the field of view that is equal to the baseline exposure level.

19. The method according to claim 18, wherein driving the array comprises reducing an output power level of the emitters.

20. The method according to claim 18, wherein driving the array comprises operating the emitters intermittently for short periods, which are interleaved with intervals in which the array is not driven to emit radiation.
